(19) United States
(12) Patent Application Publication
(10) Pub. No.: US 2011/0271655 A1
(43) Pub. Date: Nov. 10, 2011

(54) SEPARATE COOLING PLATE FOR AIRCRAFT ENGINE ELECTRIC CONTROL

(76) Inventor: Richard A. Poisson, Avon, CT (US)

(21) Appl. No.: 12/776,666

(22) Filed: May 10, 2010

(51) Int. Cl. F02C 7/12; H05K 7/20

(52) U.S. Cl. 60/39.83; 361/702

(57) ABSTRACT

An assembly has an electrical control including electrical connectors and electric circuits. The electric circuits are programmed to control an aircraft engine. The electrical control is attached to a cooling plate, which includes internal fluid passages for circulating a cooling fluid, and providing cooling to the electrical control. In a separate feature, an electric element is mounted to a cooling plate that is in turn mounted to an outer housing of an engine.

### BACKGROUND

This application relates to a cooling plate for an aircraft electric control, wherein the cooling plate is maintained separate from the control.

Aircraft engines are provided with many complex controls in modern aircraft. The engine is typically provided with an electric control that controls most aspects of the aircraft, and is known as a full authority digital engine control, or “FADEC.”

Many electric controls become quite hot during operation, and the FADEC is no exception. As such, FADECs have typically been constructed with an internal cooling circuit. A cooling fluid is circulated through the cooling circuit, and within the FADEC. Often, aircraft fuel is circulated through the cooling plate as a cooling fluid. The use of the internal cooling fluid has also been utilized for other type of electric controls mounted directly to an engine housing.

Separate cooling plates have been known for electric controls, but they have not been utilized with a FADEC, nor with an electric control which is mounted to an engine housing.

However, by having the cooling fluid circulate within the electric control, there are concerns raised with regard to leakage of fluid in the control.

### SUMMARY

An assembly has an electrical control including electrical connectors and electric circuits. The electric circuits are programmed to control an aircraft engine. The electrical control is attached to a cooling plate, which includes internal fluid passages for circulating a cooling fluid, and providing cooling to the electrical control.

In a separate feature, an electric element is mounted to a cooling plate that is in turn mounted to an outer housing of an engine.

These and other features of the present invention can be best understood from the following specification and drawings, the following of which is a brief description.

### BRIEF DESCRIPTION OF THE DRAWINGS

FIG. 1 is a cross-sectional view through an inventive arrangement.

FIG. 2 schematically shows a cooling plate fluid flow.

FIG. 3 shows the structure of FIG. 1 disassembled.

FIG. 4 shows a detail of the cooling plate.

FIG. 5 shows a detail of the FADEC.

### DETAILED DESCRIPTION

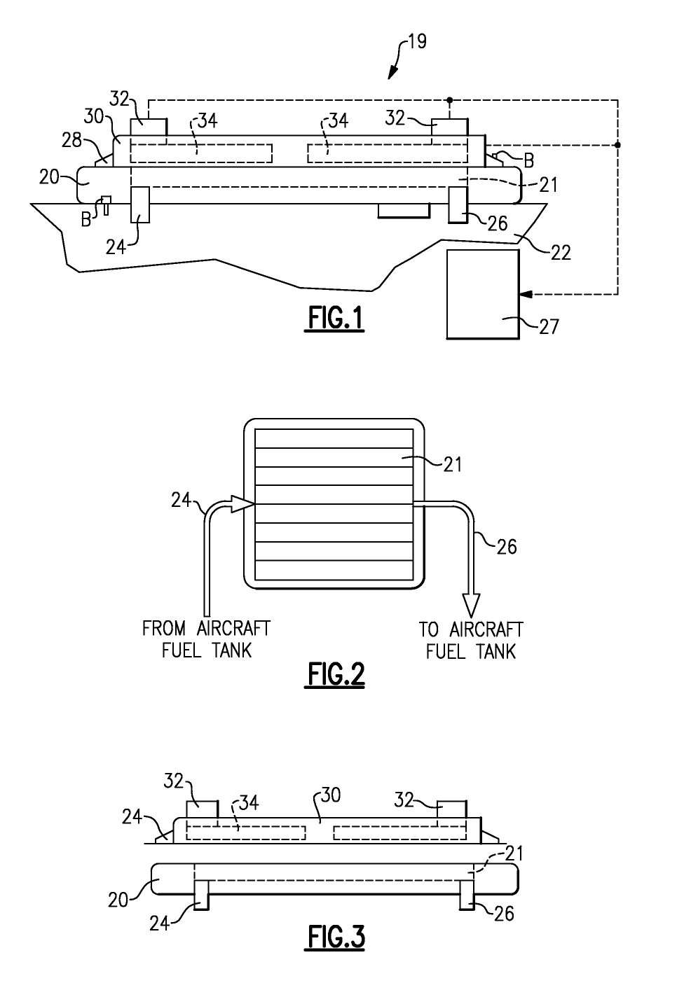

An assembly 19 is illustrated in FIG. 1 incorporating a full authority digital engine control (FADEC 30), and a cooling plate 20. The cooling plate 20 is provided with internal fluid passages forming an internal cooling circuit 21 having fluid connections 24 and 26 for circulating a cooling fluid and providing cooling to the FADEC 30. The cooling plate 20 is attached to the outer surface of an engine housing 22, which may be a gas turbine engine mounted in an aircraft controlled by the FADEC 30.

The FADEC 30 is attached to the outer surface of the cooling plate 20. Side legs 28 of the FADEC 30 are also shown in FIG. 1.

Electrical connectors 32 connect electric circuit elements 34 within the FADEC 30, and as shown by phantom line, to and from operational components 27 in the aircraft engine. The pair of electric circuit elements 34 depicted in FIG. 1 may represent electric circuits for separate channels of operation, which can be configured as a shared control (active/active) or a redundant control (active/standby). Distributing the electric circuit elements 34 in a planar manner across the FADEC 30 spreads the heat load over the surface of the cooling plate 20.

As known, a FADEC is an electrical control programmed to control any number of operational systems on the aircraft engine. Among the operational components 27 which are controlled by the FADEC 30 would be the fuel flow system, stator vane positions for variable vanes associated with the gas turbine engine compressor, bleed valve positions, and a number of other valve positions. The FADEC 30 is also operable to control engine starting and restarting. For purposes of this application, the FADEC 30 may be taken as known, and the invention would extend to any number of variations on the basic structure as outlined above.

The FADEC 30 receives multiple inputs, such as from the aircraft, which may include air density, throttle lever position, engine temperatures, engine pressures, and many other parameters. All of these inputs are utilized to control the operational components 27 to achieve desired engine characteristics, again as known.

As shown in FIG. 2, the cooling circuit 21 takes in fluid from inlet 24, and delivers it outwardly of outlet 26. The fluid may be circulated from an aircraft fuel tank, as known.

FIG. 3 shows the disassembly of the FADEC 30 from the cooling plate 20, illustrating that the FADEC 30 is physically separate and separable from the cooling plate 20. As can be appreciated, the cooling circuit 21 is positioned on an outer face of the cooling plate 20 such that it is to provide efficient and adequate cooling to the FADEC 30.

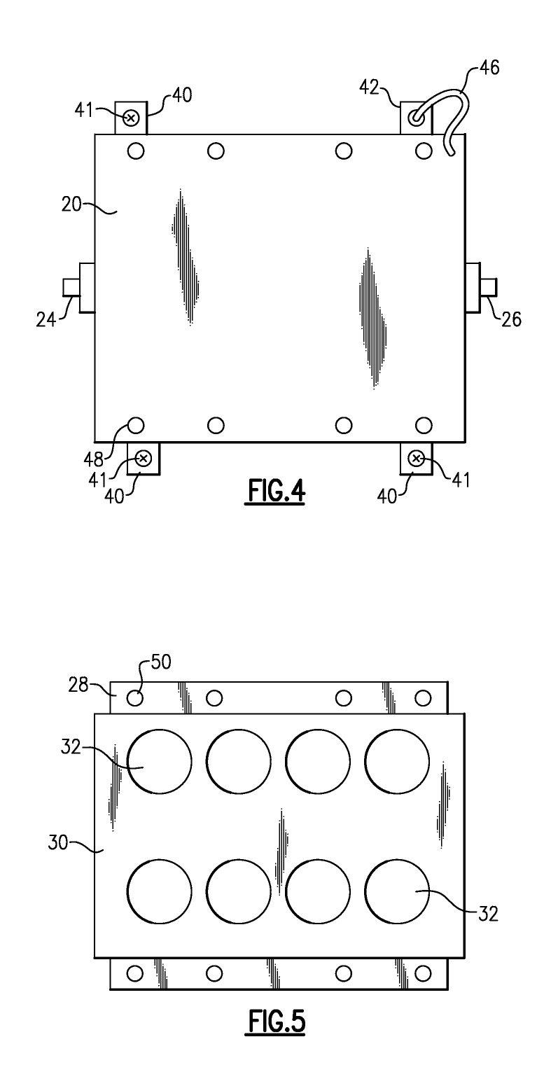

As shown in FIG. 4, the cooling plate 20 has the inlet 24, outlet 26, and a plurality of bolt legs 40. One of the bolt legs 40, shown at 42, receives a ground strap 46. The ground strap 46 is utilized to provide a ground for the FADEC 30.

The bolt legs 40 are secured to the outer surface of the engine housing 22, by receiving securing members such as bolts.

The FADEC 30 is illustrated in FIG. 5. As shown, the side legs 28 have a plurality of bolt holes 50, which are aligned with holes 48 in the cooling plate 20. As can be appreciated, the FADEC 30 is secured to the cooling plate 20 through bolts extending through holes 50 and into threaded openings of holes 48.

The cooling plate 20 may be provided with vibration isolators 41, shown schematically in FIG. 4. Vibration isolators are known, and are currently utilized to attach a FADEC directly to the engine housing 22. Further, as shown schematically in FIG. 1, bolts B secure the cooling plate 20 to the engine housing 22, and secure the FADEC 30 to the cooling plate 20.

While this application specifically discloses a FADEC mounted directly to an engine housing, it should be understood that it could apply to a FADEC mounted elsewhere. In addition, it would extend to electric controls that are distinct from being a full FADEC control, but which are mounted to an outer engine housing with an intermediate cooling plate. In fact, this feature would extend to other engine mounted electric elements beyond controls, including sensors, for example.

Although an embodiment of this invention has been disclosed, a worker of ordinary skill in this art would recognize that certain modifications would come within the scope of this invention. For that reason, the following claims should be studied to determine the true scope and content of this invention.

What is claimed is:

1. An assembly comprising:
an electrical control including electrical connectors and electric circuits, said electric circuits being programmed to control an aircraft engine; and
said electrical control being attached to a cooling plate, said cooling plate including internal fluid passages for circulating a cooling fluid, and providing cooling to said electrical control.

2. The assembly as set forth in claim 1, wherein said internal fluid passages are positioned to be on a face of said cooling plate which is spaced toward a face of said electrical control which will contact said cooling plate.

3. The assembly as set forth in claim 1, wherein said cooling plate is provided with a plurality of legs to receive securing members for securing said cooling plate to an aircraft engine housing.

4. The assembly as set forth in claim 1, wherein said electrical control is provided with legs on opposed sides of an electrical control body, and said legs being provided with openings to be aligned with openings in said cooling plate to secure said electrical control to said cooling plate.

5. The assembly as set forth in claim 1, wherein said electrical control is a full authority digital engine control.

6. The assembly as set forth in claim 5, wherein said full authority digital engine control is operable to control at least fuel flow, vane position, and the operation of valves associated with an aircraft engine.

7. A gas turbine engine comprising:
an outer housing;
operational components to combust a fuel and provide energy;
an electrical element; and
said electrical element being attached to a cooling plate, said cooling plate including internal fluid passages for circulating a cooling fluid, and providing cooling to said electric element, and said cooling plate attached to an outer surface of said outer housing.

8. The gas turbine engine as set forth in claim 7, wherein said internal fluid passages are positioned to be on a face of said cooling plate which is spaced toward a face of said electrical control which will contact said cooling plate.

9. The gas turbine engine as set forth in claim 7, wherein said cooling plate is provided with a plurality of legs to receive securing members for securing said cooling plate to said outer housing.

10. The gas turbine engine as set forth in claim 7, wherein said electric element is provided with legs on opposed sides of an electric element body, and said legs being provided with openings to be aligned with openings in said cooling plate to secure said electrical control to said cooling plate.

11. The gas turbine engine as set forth in claim 7, wherein said electric element is a control for controlling said gas turbine engine.

12. The gas turbine engine as set forth in claim 11, wherein said electrical control is a full authority digital engine control.

13. The gas turbine engine as set forth in claim 12, wherein said full authority digital engine control is operable to control at least fuel flow, vane position, and the operation of valves associated with said gas turbine engine.

14. An assembly comprising:
a full authority digital engine control including electrical connectors and electric circuits, said electric circuits being programmed to control at least fuel flow, vane position, and the operation of valves associated with an aircraft engine;
said full authority digital engine control being attached to a cooling plate, said cooling plate including internal fluid passages for circulating a cooling fluid, and providing cooling to said full authority digital engine control;
said internal fluid passages positioned to be on a face of said cooling plate which is spaced toward a face of said full authority digital engine control in contact with said cooling plate;
said cooling plate provided with a plurality of legs to receive securing members for securing said cooling plate to an aircraft engine housing; and
said full authority digital engine control provided with legs on opposed sides of an electrical control body, and said legs being provided with openings to be aligned with openings in said cooling plate to secure said full authority digital engine control to said cooling plate.
